(19) United States
(12) Patent Application Publication
(10) Pub. No.: US 2026/0047459 A1
(43) Pub. Date: Feb. 12, 2026

(54) SEMICONDUCTOR PACKAGE AND A METHOD FOR MANUFACTURING THE SAME

(71) Applicant: Samsung Electronics Co., Ltd., Suwon-si (KR)

(72) Inventor: Duckgyu KIM, Suwon-si (KR)

(73) Assignee: Samsung Electronics Co., Ltd., Suwon-si (KR)

(21) Appl. No.: 19/024,239

(22) Filed: Jan. 16, 2025

(30) Foreign Application Priority Data
Aug. 9, 2024 (KR) 10-2024-0106759

(51) Int. Cl. H01L 23/498; H01L 21/48; H01L 23/00; H01L 23/373

(52) U.S. Cl. CPC H01L 23/49838; H01L 21/4853; H01L 21/4857; H01L 23/3736; H01L 23/49816; H01L 23/49866; H01L 24/08; H01L 23/562; H01L 2224/08225; H01L 2924/1815

(57) ABSTRACT

A semiconductor package may include a redistribution structure, a semiconductor chip on a surface of the redistribution structure, a UBM pad on an opposite surface of the redistribution structure, a barrier pattern on at least a portion of a lower surface of the UBM pad and surrounding a side surface of the UBM pad, and a connection bump on the lower surface of the UBM pad.

### CROSS-REFERENCE TO RELATED APPLICATION

This application claims priority to and the benefit of Korean Patent Application No. 10-2024-0106759 filed in the Korean Intellectual Property Office on Aug. 9, 2024, the entire contents of which are incorporated herein by reference.

### BACKGROUND

### 1. Field

The present inventive concepts relate to semiconductor packages and methods for manufacturing the same.

### 2. Description of the Related Art

As electronic devices become down-sized, thinner, lighter, and more multifunctional, various technologies are being studied to improve the performance, integration, and reliability of semiconductor packages.

The semiconductor package may be mounted on a board, interposer, etc. via solder bumps formed on a redistribution structure. For dispersing stress when mounting of a semiconductor package, an Under Bump Metallurgy (UBM) pad can be applied under the solder bump. At this time, the UBM pad may be separated from the redistribution structure due to the difference in thermal expansion coefficient between the UBM pad and the passivation layer of the redistribution structure in contact therewith.

### SUMMARY

Some example embodiments of the present inventive concepts provide a semiconductor device having improved reliability and/or a method for manufacturing the same. A semiconductor device according to some example embodiments may include a redistribution structure, a semiconductor chip on a surface of the redistribution structure, a UBM pad on an opposite surface of the redistribution structure, a barrier pattern surrounding a side surface and on at least a portion of a lower surface of the UBM pad, and a connection bump on the lower surface of the UBM pad.

A semiconductor package manufacturing method according to some example embodiments may include forming a first insulating layer and a second insulating layer on a surface of a semiconductor chip, forming a redistribution structure on the second insulating layer, forming a third insulating layer on the redistribution structure, exposing a portion of the redistribution structure based on etching a portion of the third insulating layer, forming a UBM pad on the exposed portion of the redistribution structure, forming a barrier pattern surrounding a side surface of the UBM pad, the barrier pattern on at least a portion of a lower surface of the UBM pad, and forming a connection bump on both the barrier pattern and the lower surface of the UBM pad.

A semiconductor package according to some example embodiments may include a semiconductor chip including a connection pad, a molding member covering an upper surface and a side surface of the semiconductor chip, a first insulating layer covering a lower surface of the semiconductor chip and at least a portion of the connection pad, a second insulating layer on the first insulating layer, a first seed layer on the second insulating layer and connected to the connection pad, a metal pattern on the first seed layer, a third insulating layer covering both the first seed layer and the metal pattern, a UBM pad extending to be at least partially inside the third insulating layer and connected to the metal pattern, a barrier pattern extending to be at least partially inside the third insulating layer to be connected to the metal pattern, the barrier pattern surrounding a side surface of the UBM pad, the barrier pattern on at least a portion of a lower surface of the UBM pad, and a connecting bump on the lower surface of the UBM pad.

According to the present inventive concepts, a semiconductor package may include a barrier pattern between a UBM pad and an insulating layer of a redistribution structure and having a thermal expansion coefficient value between a value of a thermal expansion coefficient of the UBM pad and a value of a thermal expansion coefficient of the insulating layer. According to the present inventive concepts, the stress caused by the difference in thermal expansion coefficient between the UBM pad and the insulating layer can be alleviated (e.g., reduced, minimized, or prevented).

According to the present inventive concepts, since the barrier pattern may cover a side surface and a portion of an upper surface and/or a lower surface of the UBM pad, oxidation of the UBM pattern can be prevented (or the likelihood of such oxidation may be reduce or minimized) and the reliability of the semiconductor package can be improved.

### BRIEF DESCRIPTION OF THE DRAWINGS

FIG. 1 is a cross-sectional view of a semiconductor package according to some example embodiments.

FIG. 2 is an enlarged view of region A of FIG. 1.

FIG. 3 is a top plan view of region A of FIG. 1.

FIG. 4 is an enlarged view of a semiconductor package according to some example embodiments.

FIGS. 5, 6, 7, 8, 9, 10, 11, 12, 13, 14, 15, and 16 are drawings for explaining a semiconductor package manufacturing process according to some example embodiments.

### DETAILED DESCRIPTION

Hereinafter, with reference to accompanying drawings, various embodiments of the present inventive concepts will be described in detail so that a person of an ordinary skill can easily implement the present inventive concepts. The present inventive concepts may be implemented in many different forms and is not limited to the example embodiments described herein.

In order to clearly explain the present inventive concepts, parts that are not relevant to the description are omitted, and identical or similar components are assigned the same reference numerals throughout the specification.

In addition, the size and thickness of each component shown in the drawings are shown arbitrarily for convenience of explanation, so the present inventive concepts are not necessarily limited to what is shown. In the drawings, the thickness of layers, films, panels, regions, etc., are exaggerated for clarity. And in the drawings, for convenience of explanation, the thicknesses of some layers and regions are exaggerated.

Throughout the specification, when a part is said to be “connected” to another part, this includes not only “directly connected” but also “indirectly connected” through another member. In a similar sense, this includes being “physically connected” as well as being “electrically connected”. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. In addition, being “on” or “above” a reference element means being positioned on or below the reference element, and does not necessarily mean being positioned “above” or “on” in a direction opposite to gravity.

In addition, unless explicitly described to the contrary, the word “comprise”, and variations such as “comprises” or “comprising”, will be understood to imply the inclusion of stated elements but not the exclusion of any other elements. In addition, throughout the specification, when referring to “a plane view”, it means that the target portion is viewed from above, and when referring to “a cross-section view”, it means that a cross section of the target portion cut vertically is viewed from a side.

In addition, throughout the specification, sequential numbers such as first and second are used to distinguish a certain component from other components that are the same or similar to the component, and are not necessarily intended to refer to a specific component. Accordingly, a component referred to as a first component in a specific part of this specification may be referred to as a second component in other parts of this specification.

Additionally, throughout the specification, references to a single element include references to a plurality of the element, unless specifically stated to the contrary. For example, “insulating layer” may be used to mean not only single insulating layer, but also a plurality of insulating layers, such as two, three or more.

Additionally, throughout the specification, references to one surface and the other surface are intended to distinguish two different surfaces and are not necessarily intended to be limited to a particular surface. Therefore, a surface referred to as one surface in a particular part of this specification may be referred to as the other side in another part of this specification.

Further, throughout the specification, the phrase “in a plan view” means when an object portion is viewed from above, and the phrase “in a cross-sectional view” means when a cross-section taken by vertically cutting an object portion is viewed from the side.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that surfaces which may be referred to as being “flat” may be understood to be “planar” or “substantially planar.” It will be understood that surfaces which may be referred to as being “planar” may be “planar” or may be “substantially planar.” Surfaces that are “substantially planar” will be understood to be “planar” within manufacturing tolerances and/or material tolerances and/or have surface portions with a deviation in magnitude and/or angle from “planar,” respectively, with regard to the other portions of the surfaces that is equal to or less than 10% (e.g., a. tolerance of ±10%).

It will be understood that elements and/or properties thereof may be recited herein as being “identical”, “the same”, or “equal” as other elements and/or properties thereof, and it will be further understood that elements and/or properties thereof recited herein as being “identical” to, “the same” as, or “equal” to other elements and/or properties thereof may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to, equal to or substantially equal to, and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element or property is referred to as being identical to, equal to, or the same as another element or property, it should be understood that the element or property is the same as another element or property within a desired manufacturing or operational tolerance range (e.g., ±10%).

It will be understood that elements and/or properties thereof described herein as being “substantially” the same, equal, and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” or “positioned apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

Hereinafter, a semiconductor package according to some example embodiments of the present inventive concepts will be described with reference to the drawings.

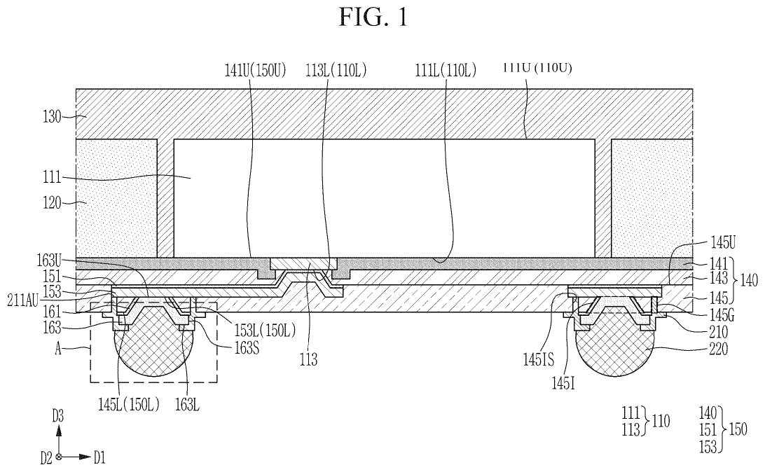

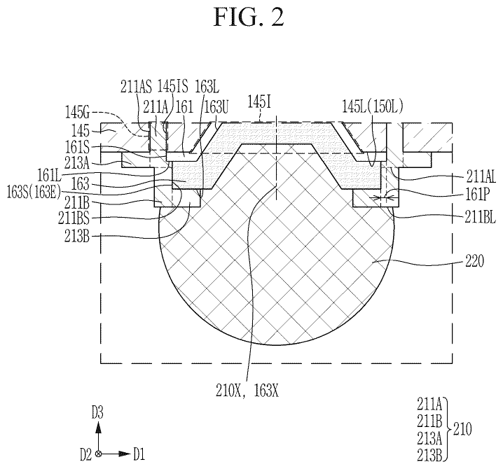

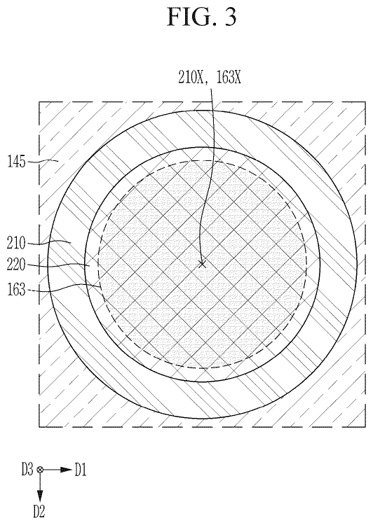

FIG. 1 to FIG. 3 are drawings for explaining a semiconductor package according to some example embodiments. Specifically, FIG. 1 is a cross-sectional view of a semiconductor package according to some example embodiments, FIG. 2 is an enlarged view of region A of FIG. 1, and FIG. 3 is a top plan view of region A of FIG. 1.

A semiconductor package according to some example embodiments may include a semiconductor chip 110, a redistribution structure 150 positioned on a lower surface 110L of the semiconductor chip 110 (e.g., such that the semiconductor chip 110 is on a surface, such as an upper surface 150U, of the redistribution structure 150), a UBM pad 163 positioned on a lower surface 150L of the redistribution structure 150, a barrier pattern 210 surrounding (e.g., covering, which may include directly contacting) a side surface 163S and on at least a portion of a lower surface 163L of the UBM pad 163, and a connection bump 220 positioned on the lower surface 163L of the UBM pad 163.

The semiconductor chip 110 may include a main device 111 and a connection pad 113 on a lower surface of the main device 111. The main device 111 may have an active surface (the lower surface 111L of the main device 111 in FIG. 1) where the connection pad 113 is positioned, and an inactive surface (the upper surface 111U of the main device 111 in FIG. 1, which may define the upper surface 110U of the semiconductor chip 110) opposite the active surface.

The main device 111 may include an IC (Integrated Circuit). The IC may be any type of integrated circuit including a memory circuit, a logic circuit, or a combination thereof. The memory circuit may be, for example, a dynamic random access memory (DRAM) circuit, a static random access memory (SRAM) circuit, a flash memory circuit, and an electrically erasable and programmable read-only memory (EEPROM), a phase-change random access memory (PRAM) circuit, a magnetic random access memory (MRAM) circuit, a resistive random access memory (RRAM) circuit, or a combination thereof.

The logic circuits may be, for example, a central processing unit (CPU) circuit, a graphic processing unit (GPU) circuit, a controller circuit, an application specific integrated circuit (ASIC) circuit, and an application processor (AP) circuit, or a combination thereof. The integrated circuit IC may include a substrate. The substrate may include a semiconductor material, for example, a group IV semiconductor material, a group III-V semiconductor material, a group II-VI semiconductor material, or any combination thereof. The group IV semiconductor materials may include, for example, silicon (Si), germanium (Ge), or any combination thereof. The group III-V semiconductor material may include, for example, gallium arsenide (GaAs), indium phosphide (InP), gallium phosphide (GaP), indium arsenide (InAs), indium antimony (InSb), indium gallium arsenide (InGaAs), or any combination thereof. The group II-VI semiconductor material may include, for example, zinc telluride (ZnTe), cadmium sulfide (CdS), or any combination thereof.

The connection pad 113 may electrically connect the semiconductor chip 110 to other components. In some example embodiments, the semiconductor chip 110 may be electrically connected to the redistribution structure 150 via the connection pad 113. The connection pad 113 may be positioned on a lower surface 111L of the main device 111. In FIG. 1, only one connection pad 113 is shown on the lower surface 111L of the main device 111, but two or more connection pads 113 may be positioned on the lower surface 111L of the main device 111 in some example embodiments.

The connection pad 113 may include conductive material. For example, the connecting pad 113 may include copper (Cu), aluminum (Al), silver (Ag), gold (Au), tungsten (W), titanium (Ti), or any combination thereof.

The redistribution structure 150 may be positioned on the active surface of the semiconductor chip 110. In some example embodiments, a flat area (i.e., an area of a cross-section perpendicular to the third direction D3) of the redistribution structure 150 may be larger than a flat area of the semiconductor chip 110. In other words, the semiconductor package according to some example embodiments may be a fan-out type. However, example embodiments are not limited thereto and, unlike the example embodiments shown in FIG. 1 to FIG. 3, the semiconductor package according to some example embodiments may be a fan-in type.

The redistribution structure 150 may include a plurality of insulating layers 141, 143 145 and metal patterns 153, which are stacked in a vertical direction (e.g., the third direction D3, which may extend perpendicular to a surface of the semiconductor chip 110 and/or the redistribution structure 150, for example the lower surface 111L). The metal patterns 153 may be positioned inside the insulating layers 141, 143, 145, for example between uppermost and lowermost surfaces of the insulating layers 141, 143, 145, for example between an upper surface 141U of the first insulating layer 141 and a lower surface 145L of the third insulating layer 145. Although only three insulating layers 141, 143, 145 are shown in FIG. 1, the redistribution structure 150 may include more or fewer insulating layers 140. Although only two metal patterns 153 are shown in FIG. 1, the redistribution structure 150 may include fewer or more metal patterns 153. The redistribution structure 150 may perform various functions depending on designs, and may include, for example, a signal pattern, a power pattern, a ground pattern, etc.

In some example embodiments, the insulating layers 141, 145, 145 may include insulating material. For example, the first insulating layer 141, the second insulating layer 143, and the third insulating layer 145 may respectively include a thermosetting resin such as an epoxy resin, a thermoplastic resin such as a polyimide, or a resin in which inorganic fillers or/and glass fibers are immersed, for example, prepreg, ABF (Ajinomoto Build-up Film), FR-4, or BT. For example, each of the first insulating layer 141, the second insulating layer 143, and the third insulating layer 145 may include a photosensitive resin such as PID (Photo-Imageable Dielectrics). In some example embodiments, the insulating layers 141, 143, 145 may include the same insulating material. However, example embodiments are not limited thereto, and the insulating layers 141, 143, 145 may respectively include insulating materials that are different from each other (e.g., the insulating layers 141, 143, 145 may include different insulating materials).

The first insulating layer 141 may be positioned below the semiconductor chip 110. For example, the first insulating layer 141 may be positioned directly below the semiconductor chip 110. The first insulating layer 141 may cover at least a portion of the lower surface 111L of the main device 111 of the semiconductor chip 110. The first insulating layer 141 may cover a side surface and a portion of a lower surface 113L of the connection pad 113. The other portion of the lower surface 113L of the connecting pad 113 may not be covered by the first insulating layer 141.

The second insulating layer 143 may be positioned below the first insulating layer 141. The second insulating layer 143 may cover a lower surface of the first insulating layer 141. The second insulating layer 143 may cover a portion, which is not covered by the first insulating layer 141, of a lower surface 113L of the connection pad 113.

The metal patterns 153 may be positioned below the second insulating layer 143. The metal patterns 153 may be positioned on at least a portion of a lower surface of the second insulating layer 143. The metal patterns 153 may cover at least a portion of the lower surface of the second insulating layer 143. In some example embodiments, at least some of the metal patterns 153 may be connected to the connection pad 113. For example, referring to FIG. 1, among the metal patterns 153, a metal pattern 153 positioned on a left side may be connected to the lower surface 113L of the connection pad 113 through an opening formed at (e.g., defined by one or more surface of) the second insulating layer 143.

A semiconductor package according to some example embodiments may include a first seed layer 151 positioned on an upper surface of a metal pattern 153. The first seed layer 151 may be positioned at an interface between the metal pattern 153 and the second insulating layer 143. The first seed layer 151 may be positioned at an interface between the metal pattern 153 and the connection pad 113 too. The first seed layer 151 may be positioned conformally along the profile of the upper surface of the metal pattern 153. The first seed layer 151 is positioned at an interface between a portion of the upper surface of the metal pattern 153 and a portion of a lower surface 113L of the connection pad 113, and may electrically connect the metal pattern 153 and the connection pad 113.

The metal pattern 153 and the first seed layer 151 may include a conductive material. For example, the metal pattern 153 and the first seed layer 151 may be made of aluminum (Al), copper (Cu), gold (Au), silver (Ag), platinum (Pt), tin (Sn), chromium (Cr), palladium (Pd), lead (Pb), titanium (Ti), or any alloy thereof, but example embodiments are not limited to. In some example embodiments, the metal pattern 153 and the first seed layer 151 may include different conductive materials. For example, the metal pattern 153 may include copper (Cu), and first seed layer 151 may include titanium (Ti).

The UBM pad 163 may be positioned on (e.g., beneath) a lower surface 153L of the metal pattern 153, where the lower surface 153L may at least partially define a lower surface 150L of the redistribution structure 150. The UBM pad 163 may be positioned on (e.g., beneath) at least a portion of the lower surface 145L of the third insulating layer 145 too, where the lower surface 145L may at least partially define a lower surface 150L of the redistribution structure 150. The UBM pad 163 may be positioned between the connection bump 220 and the redistribution structure 150 to strengthen the adhesion of the connection bump 220, which may improve the reliability of the semiconductor package.

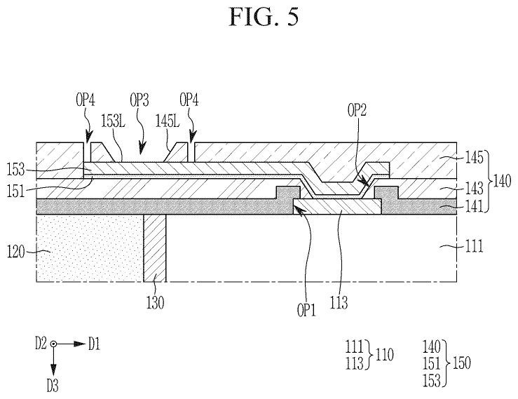

Referring to FIG. 1 to FIG. 3, the UBM pad 163 may have a shape of which a portion of the UBM pad 163 is curved toward the lower surface 153L of metal pattern 153. In some example embodiments, the UBM pad 163 may be positioned along a side surface and bottom surface of a third opening (OP3, see FIG. 5) formed at the third insulating layer 145. The UBM pad 163 may be connected to a portion of the lower surface 153L of the metal pattern 153 through a third opening (OP3, see FIG. 5) formed at the third insulating layer 145. The UBM pad 163 may have a shape of reversed ‘U’ in a cross-sectional view shown in FIG. 1 and FIG. 2.

The UBM pad may have a circular shape on a plane (e.g., a plane extending in the first and second directions D1 and D2). Unlike shown in FIG. 3, the UBM pad 163 may have an elliptical shape in a plan view. At least a portion of the UBM pad 163 may overlap the metal pattern 153 in a third direction D3. The first and second directions D1 and D2 may each be referred to herein as a horizontal direction. As described herein, a horizontal direction (e.g., the first direction D1 and/or the second direction D2) may be a direction extending in parallel to an in-plane direction of the redistribution structure 150, for example a direction extending in parallel to at least a portion of an upper surface 150U of the redistribution structure 150, for example at least a portion of the upper surface 141U defining at least a portion of the upper surface 150U. As described herein, a horizontal direction (e.g., the first direction D1 and/or the second direction D2) may be a direction extending in parallel to an in-plane direction of the semiconductor chip 110, for example in parallel to an upper surface 110U and/or a lower surface 110L of the semiconductor chip 110. The first and second directions D1 and D2 may extend perpendicular to each other. The third direction D3 may be referred to herein as a vertical direction. As described herein, a vertical direction (e.g., the third direction D3) may be a direction extending perpendicular to an in-plane direction of the redistribution structure 150, for example extending perpendicular to an upper surface 150U of the redistribution structure. As described herein, a vertical direction (e.g., the third direction D3) may be a direction extending perpendicular to an in-plane direction of the semiconductor chip 110, for example extending perpendicular to an upper surface 110U and/or a lower surface 110L of the semiconductor chip 110. The vertical direction (e.g., the third direction D3) may extend perpendicular to the first and second directions D1 and D2.

A semiconductor package according to some example embodiments may include a second seed layer 161 positioned on an upper surface 163U of the UBM pad 163. The second seed layer 161 may be positioned at an interface between the UBM pad 163 and the third insulating layer 145. The second seed layer 161 may be positioned at an interface between the UBM pad 163 and the metal pattern 153 too. The second seed layer 161 may be positioned conformally along a profile of the upper surface 163U of the UBM pad 163. The second seed layer 161 may be positioned at an interface between a portion of the upper surface 163U of the UBM pad 163 and a portion of the lower surface 153L of the metal pattern 153, and may electrically connect the UBM pad 163 and the metal pattern 153.

Referring to FIG. 1 to FIG. 3, the second seed layer 161 may be positioned along a side surface and bottom surface of the third opening (OP3, see FIG. 5) formed at the third insulating layer 145. A portion, which positioned on a lower surface of the third opening (OP3, see FIG. 5), of the second seed layer 161 may contact the lower surface 153L of the metal pattern 153. The second seed layer 161 may electrically connect the metal pattern 153 and the UBM pad 163.

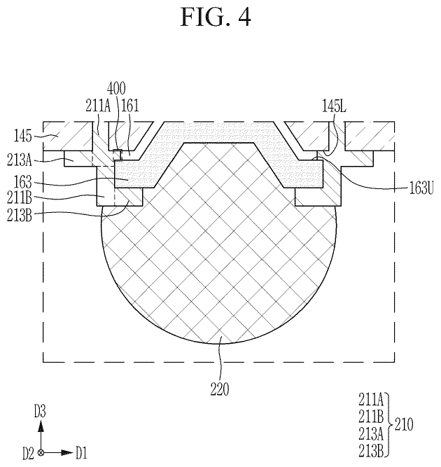

The second seed layer 161 may have a circular shape on a plane (e.g., a plane extending in the first and second directions D1 and D2). On a plane (e.g., a plane extending in the first and second directions D1 and D2), the second seed layer 161 may have a diameter larger than the diameter of the UBM pad 163. On a plane (e.g., in a plane extending in the first and second directions D1 and D2), a center of the second seed layer 161 may overlap with a center of the UBM pad 163 in the third direction D3. In a plan view, the second seed layer 161 may be further protruded (e.g., may be further protruded in the first and/or second direction D1 and/or D2) from the outer edge 163E of the UBM pad 163 (e.g., periphery) by a particular (or, alternatively, predetermined) length 161P in an outward direction (e.g., in the first and/or second directions). An outer side surface (e.g., side surface 161S) of the second seed layer 161 may be positioned to protrude further outward (e.g., may protrude further from the center 163X and/or central axis of the UBM pad 163 in a horizontal direction that as described herein may include the first and/or second directions D1 and/or D2) than the outer side surface (e.g., side surface 163S) of the UBM pad 163. The semiconductor package according to some example embodiments may not include an undercut region, which will be described later with reference to FIG. 4. A portion, which is protruded further outward than the outer side surface (e.g., side surface 163S) of the UBM pad 163, of the second seed layer 161 may be covered at least in part by the barrier pattern 210 that will be described below. For example, referring to FIG. 2, the side surface 161S and a portion of the lower surface 161L of a portion, which is protruded further outward than the outer side surface (e.g., side surface 163S) of the UBM pad 163, of the second seed layer 161 may be covered by the barrier pattern 210. As described herein, a plane that extend parallel to the first and second directions D1 and D2 may include, for example, an upper surface 150U of the redistribution structure 150 (e.g., at least a portion thereof as defined by at least the upper surface 141U of the first insulation layer 141) upon which the semiconductor chip 110 may be positioned.

A semiconductor package according to some example embodiments may include a barrier pattern 210 surrounding at least a portion of the UBM pad 163 and the second seed layer 161. Specifically, the barrier pattern 210 may cover the side surface 163S of the UBM pad 163. The barrier pattern 210 may cover a portion of the lower surface 163L of the UBM pad 163 too. The barrier pattern 210 may cover the side surface 161S of the second seed layer 161. The barrier pattern 210 may also cover a portion of the lower surface 161L of the second seed layer 161. An element described herein to “cover” another element or a portion thereof may be interchangeably referred to as directly contacting (e.g., may be understood to directly contact) the other element or the portion thereof, but example embodiments are not limited thereto.

The barrier pattern 210 may have a ring shape on a plane (e.g., in a plane extending in the first and second directions D1 and D2). On a plane, the outer diameter of the barrier pattern 210 may be larger than the diameters of the UBM pad 163 and the second seed layer 161. On a plane, the inner diameter of the barrier pattern 210 may be smaller than the diameters of the UBM pad 163 and the second seed layer 161. On a plane, a center 210X of the barrier pattern 210 (e.g., a central axis thereof) may overlap a center 163X of the UBM pad 163 (e.g., a central axis thereof) in the third direction D3 (e.g., the barrier pattern 210 and the UBM pad 163 may define respective central axes that are coaxial with each other). In some example embodiments, the barrier pattern 210 may include a portion overlapping UBM pad 163 in the third direction D3. The portion, which overlaps UBM pad 163 in the third direction D3, of barrier pattern 210 may be a portion, which covers the lower surface of the UBM pad 163, of barrier pattern 210.

The barrier pattern 210 according to some example embodiments may include a first body portion 211A, a first protruding portion 213A, a second body portion 211B, and a second protruding portion 213B. The first body portion 211A, the first protruding portion 213A, the second body portion 211B, and the second protruding portion 213B are portions of the barrier pattern 210, which are sectored for better understanding and convenience of description, and the regions may not be separated from each other and may be formed integrally (e.g., may be separate portions of a single, unitary piece of material).

The first body portion 211A may be extended (e.g., in the third direction D3) to inside of the third insulating layer 145, for example to extend to an inside of the third insulating layer 145 that is an inside region 145G (e.g., an “inside” of the third insulating layer 145) defined by one or more inner surfaces 145IS of the third insulating layer 145 between the lower surface 145L and the upper surface 145U of the third insulating layer 145 in the third direction D3. The portion of the first body portion 211A that extends to the inside of the third insulating layer 145 (e.g., extends into the inside region 145G) may be connected to (e.g., may directly contact) the metal pattern 153, such that the barrier pattern 210 may be connected to (e.g., may directly contact) the metal pattern 153. A side surface 211AS of the first body portion 211A extended to inside of the third insulating layer 145 may be covered by the third insulating layer 145. Referring to FIG. 1 and FIG. 2, the first body portion 211A is extended to inside of the third insulating layer 145, and an end of the first body portion 211A may be connected to (e.g., may directly contact) the lower surface 153L of the metal pattern 153.

First, an upper surface 211AU of the first body portion 211A may contact a portion of the lower surface 153L of the metal pattern 153. However, example embodiments are not limited thereto. In some example embodiments, the first body portion 211A is not connected to (e.g., is spaced apart from) the metal pattern 153, and an end of the first body portion 211A (e.g., upper surface 211AU) may be positioned apart from (e.g., spaced apart from) the lower surface 153L of the metal pattern 153 in the third direction D3. In this case, the side surface 211AS and upper surface 211AU of the first body portion 211A extended into the inside of the third insulating layer 145 (e.g., extends to be at least partially inside the third insulating layer 145, for example at least partially within the inside region 145G defined by one or more inner surfaces 145IS between the upper and lower surfaces 145U and 145L in the third direction D3) may be covered by (e.g., directly contacted by) the third insulating layer 145.

First, a portion of the first body portion 211A may protrude further downward (e.g., away from the semiconductor chip 110 in the third direction D3) than the lower surface 145L of the third insulating layer 145. The lower surface 211AL of the first body portion 211A may be positioned lower (e.g., further from the semiconductor chip 110 in the third direction D3) than the lower surface 145L of the second seed layer 161. The first body portion 211A may overlap the side surface 161S of the second seed layer 161 and at least a portion of the UBM pad 163 in the horizontal direction (e.g., the first and/or second direction D1 and/or D2). The first body portion 211A may cover the side surface 161S of the second seed layer 161 and at least a portion of the side surface 163S of the UBM pad 163. Referring to FIG. 2, the first body portion 211A may include a portion protruded in a direction (e.g., the first direction D1 and/or the second direction D2) from an inner side surface toward the UBM pad 163, and the portion protruded in a direction from the inner side surface toward the UBM pad 163 may cover a portion of the lower surface 161L of the second seed layer 161.

The first protruding portion 213A may protrude outwardly (e.g., away from the center 210X of the barrier pattern 210 as shown in FIGS. 2 and 3 in the first and/or second directions D1 and/or D2, for example in a direction extending radially away from a central axis of the barrier pattern 210 in the first and/or second directions D1 and/or D2) from an outer side surface (e.g., side surface 211AS) of the first body portion 211A. Specifically, the first protruding portion 213A may be protruded outwardly from the outer side surface, which is protruded below the third insulating layer 145, of the first body portion 211A. Although not explicitly shown in FIG. 1 to FIG. 3, the first body portion 211A may have a ring shape in a plane, and the first protruding portion 213A may protrude outwardly from an outer circumference surface of the ring shaped first body portion 211A. In some example embodiments, the first protruding portion 213A may be positioned below the lower surface of the third insulating layer 145. The upper surface of the first protruding portion 213A may cover at least a portion of the lower surface of the third insulating layer 145.

The second body portion 211B may be positioned below the first body portion 211A. The second body portion 211B may be positioned on the lower surface 211AL of the first body portion 211A. The upper surface of the second body portion 211B may contact the lower surface of the first body portion 211A. The second body portion 211B may overlap at least a portion of the UBM pad 163 in a horizontal direction (e.g., the first and/or second directions D1 and/or D2). Specifically, the second body portion 211B may overlap the remaining portion, which does not overlap (e.g., is exposed from) the first body portion 211A in a horizontal direction, of the UBM pad 163 in a horizontal direction (e.g., the first and/or second directions D1 and/or D2). The second body portion 211B may cover at least a portion of the UBM pad 163. Specifically, the second body portion 211B may cover the remaining side surface 163S, which does not overlap the first body portion 211A in a horizontal direction, of the UBM pad 163 in a horizontal direction. In some example embodiments, the lower surface 211BL of the second body portion 211B may be positioned lower than (e.g., further from the semiconductor chip 110 in the third direction D3 than) the lower surface 153L of the metal pattern 153.

The second protruding portion 213B may be protruded inwardly (e.g., towards the center 210X of the barrier pattern 210 as shown in FIGS. 2 and 3 in the first and/or second directions D1 and/or D2, for example in a direction extending radially towards a central axis of the barrier pattern 210 in the first and/or second directions D1 and/or D2) from the inner side surface of the second body portion 211B. Specifically, the second protruding portion 213B may protrude inwardly from the inner side surface 211BS of a portion of the second body portion 211B positioned below the lower surface of the UBM pad 163. In some example embodiments, the second protruding portion 213B may be protruded inwardly from the inner side surface 211BS of the ring shaped second body portion 211B. The second protruding portion 213B may be protruded inwardly from the inner circumference surface of the ring shaped second body portion 211B (which may be at least partially defined by the inner side surface 211BS).

In a semiconductor package according to some example embodiments, the barrier pattern 210 covers the side surfaces 163S, 161S and at least a portion of the lower surface 163L 161L of the UBM pad 163 and the second seed layer 161, and at least a portion of the third insulating layer 145, and a portion of the barrier pattern 210 may be extended to inside of the third insulating layer 145. For example, the barrier pattern 210 may extend to be at least partially inside the third insulating layer 145 such that at least a portion of the barrier pattern 210 extends to be within an inside region 1451 (e.g., an “inside” of the third insulating layer 145) defined between a lowermost and uppermost level, in the third direction D3, of the respective lower and upper surfaces 145L and 145U of the third insulating layer 145). As described herein, an element that is described to be extended to an “inside” of a layer may be understood to extend such that at least a portion of the element is extends at least partially through a thickness of the layer to be at least partially between opposite surfaces (e.g., upper and lower surfaces) of the layer. Through this structure, the adhesion of the UBM pad 163 and the second seed layer 161 to the third insulating layer 145 may be strengthened.

In a semiconductor package according to some example embodiments, the side surface 161S, 163S and a portion of the lower surface 161L, 163L of the second seed layer 161 and the UBM pad 163 may be covered by the barrier pattern 210, thereby the second seed layer 161 and the UBM pad 163 may be prevented from oxidation, or the likelihood of such oxidation may be reduced or minimized.

When forming the second seed layer 161, the second seed layer 161 may be sufficiently etched to prevent a short circuit from occurring due to contact with other second seed layers 161 positioned nearby, or with contaminating materials positioned on a lower surface of the third insulating layer 145 (or reduce or minimize the risk of such a short circuit from occurring). At this time, the second seed layer 161 may be over-etched so that an undercut region between the third insulating layer 145 and the UBM pad 163 may be formed. If an undercut region is positioned between the third insulating layer 145 and the UBM pad 163, the UBM pad 163 may easily delaminate or a crack may occur in the insulating layer 140. In a semiconductor package according to some example embodiments, since the barrier pattern 210 may cover the second seed layer 161, and thus the second seed layer 161 is not required to be over-etched, an undercut region may not be formed between the third insulating layer 145 and the UBM pad 163.

In some example embodiments, the barrier pattern 210 may include a material having a thermal expansion coefficient between a thermal expansion coefficient of an insulating material included in at least one of the insulating layers 141, 143, 145 and a thermal expansion coefficient of a material included in the UBM pad 163. For example, a thermal expansion coefficient of the barrier pattern 210 and/or of a material thereof may have a value that is between a value of a thermal expansion coefficient of an insulating material included in at least one of the insulating layers 141, 143, 145 and a value of a thermal expansion coefficient of a material included in the UBM pad 163. For example, if the UBM pad 163 includes copper (Cu) and the third insulating layer 145 includes polyimide, the barrier pattern 210 may include a material having a thermal expansion coefficient between the thermal expansion coefficient of copper (Cu) and the thermal expansion coefficient of the polyimide (e.g., the barrier pattern 210 may include a material having a thermal expansion coefficient value that is between the value of the thermal expansion coefficient of copper (Cu) and the value of the thermal expansion coefficient of the polyimide).

For example, the thermal expansion coefficient of the material included in barrier pattern 210 (e.g., the value of such thermal expansion coefficient) may be greater than about 16.7 and less than about 35. For example, the thermal expansion coefficient of the material included in barrier pattern 210 (e.g., the value of such thermal expansion coefficient) may be greater than about 16.7 and less than about 60.

In some example embodiments, the barrier pattern 210 may include at least one material selected from the group consisting of aluminum (Al), tin (Sn), and silver (Ag). For example, the barrier pattern 210 may comprise at least one of aluminum, silver, or tin. It was described that materials included in barrier pattern 210 are metal materials (e.g., Al, Sn, Ag) as an example, but materials included in barrier pattern 210 are not limited to metal. For example, the barrier pattern 210 may include a non-metallic material having a thermal expansion coefficient between the thermal expansion coefficients of insulating layers 141, 143, 145 and the thermal expansion coefficient of the UBM pad 163.

In some example embodiments, the barrier pattern 210 may cover at least a portion of the UBM pad 163 and the insulating layers 141, 143, 145, and the thermal expansion coefficient of the barrier pattern 210 may have a value between the value of the thermal expansion coefficient of the UBM pad 163 and the value(s) of the thermal expansion coefficient of the insulating layers 141, 143, and 145. Accordingly, when a semiconductor package according to some example embodiments is alternately exposed to high temperature and low temperature, the physical stress due to the difference in thermal expansion coefficient between the UBM pad 163 and the insulating layers 141, 143, and 145 can be alleviated (e.g., reduced, minimized, or prevented), so that the reliability of the semiconductor package can be improved.

Connection bumps 220 may be positioned below the UBM pad 163. The connection bumps 220 may electrically connect the semiconductor package according to some example embodiments to an external device. Each of the connection bumps 220 may be connected to a redistribution structure 150 via the UBM pads 163. The connection bumps 220 may contain metal material. For example, the connection bumps 220 may have a spherical shape or a ball shape made of a low melting point metal such as tin (Sn), indium (In), bismuth (Bi), antimony (Sb), copper (Cu), silver (Ag), zinc (Zn), lead (Pb) or any alloy thereof (e.g., Sn—Ag—Cu).

A semiconductor package according to some example embodiments may further include a support member 120 positioned on an upper surface of the redistribution structure 150.

The support member 120 may improve the rigidity of the semiconductor package according to some example embodiments. The support member 120 may be formed so that an upper surface of the molding member 130 that will be described later is formed flat. The support member 120 may include a cavity exposing an upper surface of the redistribution structure 150. The semiconductor chip 110 may be mounted in a cavity formed in the support member 120.

The support member 120 may include various insulating materials including thermosetting resin such as epoxy resin, thermoplastic resins such as polyimide or, or glass fiber composite material. When the support member 120 includes a high rigidity material, the support member 120 may reduce warpage of the semiconductor package.

The molding member 130 may protect the semiconductor chip 110 and the redistribution structure 150. The molding member 130 may cover the redistribution structure 150, the semiconductor chip 110, and the support member 120, and may at least partially fill a space between the semiconductor chip 110 and the support member 120, and a space between the semiconductor chip 110 and the redistribution structure 150.

The molding member 130 may include, for example, a thermosetting resin, a thermoplastic resin, a UV curable resin, or a combination thereof. The molding member 130 may include, for example, epoxy resin, silicone resin, or a combination thereof. The molding member 130 may include, for example, an epoxy mold compound (EMC).

FIG. 4 is an enlarged view of a semiconductor package according to some example embodiments. Specifically, FIG. 4 is an enlarged view of a region A of FIG. 1. FIG. 4 may be a drawing showing some example embodiments other than the semiconductor package described with reference to FIG. 2 and FIG. 3. Since the semiconductor package illustrated in FIG. 4 is the same as the semiconductor package described with reference to FIG. 1 to FIG. 3 in many parts, the following explanation will focus on differences. Specifically, the semiconductor package illustrated in FIG. 4 may differ from the preceding embodiments in that an undercut region is formed between the UBM pad 163 and the third insulating layer 145.

Referring to FIG. 4, in a semiconductor package according to some example embodiments, an undercut region 400 may be formed between the UBM pad 163 and the third insulating layer 145, for example to be at least partially defined between an upper surface 163U of the UBM pad 163 and a lower surface 145L of the third insulating layer 145 in the third direction D3. The undercut region 400 may be formed by overetching the second seed layer 161 by an etchant during the process of patterning the second seed layer 161. In a semiconductor package according to some example embodiments, a barrier pattern 210 (e.g., at least a portion of the barrier pattern 210) may be positioned in the undercut region 400 formed between the UBM pad 163 and the third insulating layer 145. Specifically, the first body portion 211A of barrier pattern 210 may fill the undercut region 400.

According to some example embodiments, even if the second seed layer 161 is overetched by the etchant in a process of patterning the second seed layer 161, the undercut region 400 may be filled by the barrier pattern 210. According to some example embodiments, the phenomenon, due to the undercut region 400, that the UBM pad 163 is easily delaminated or cracks occur in the insulating layer 140 may be improved (e.g., the likelihood of such phenomenon may be reduced, minimized, or prevented).

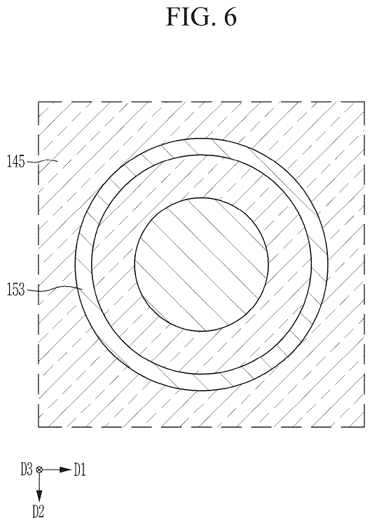

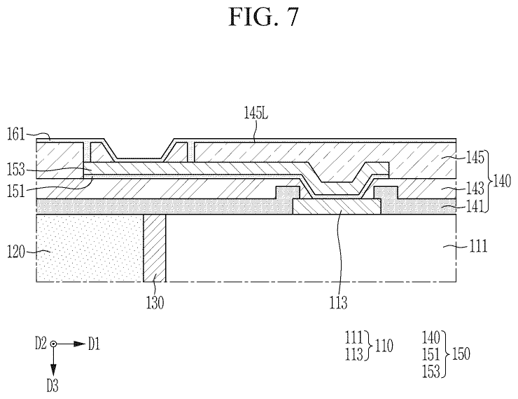

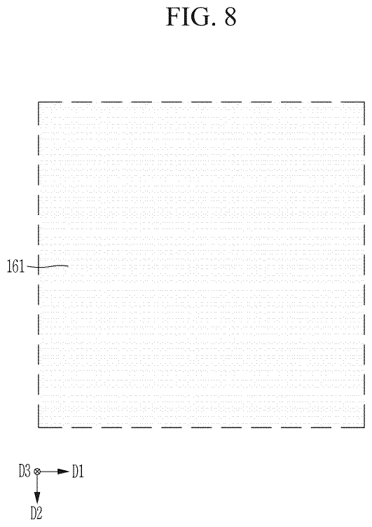

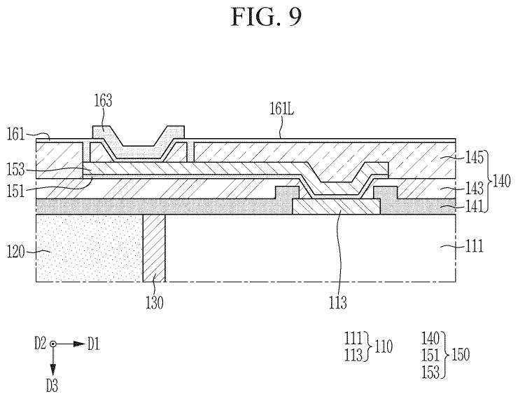

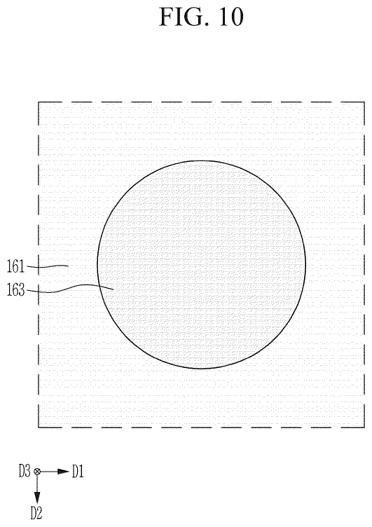

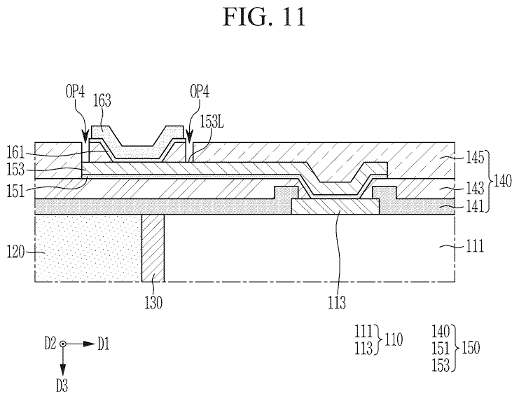

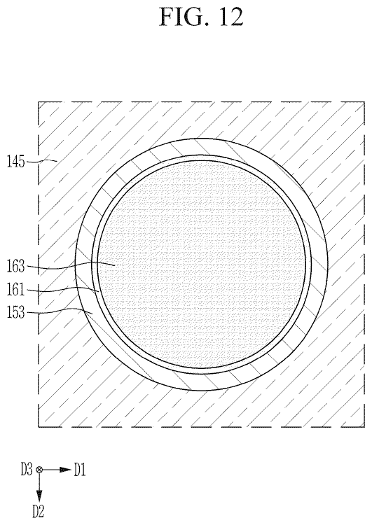

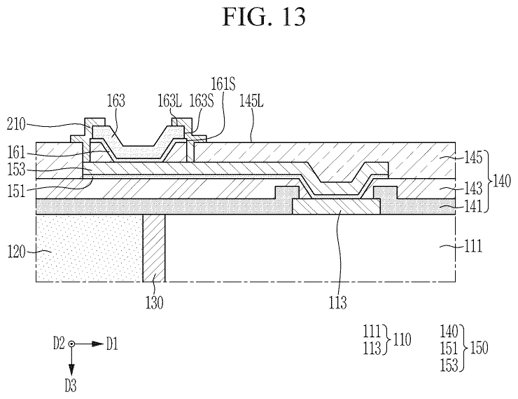

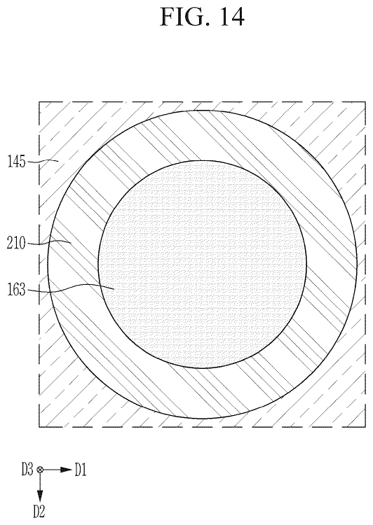

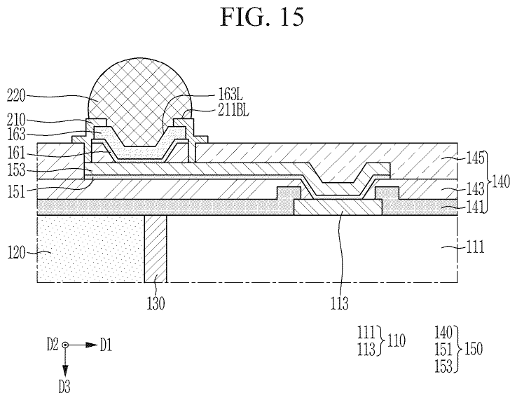

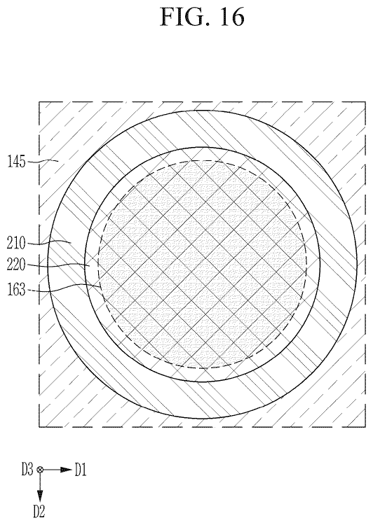

FIGS. 5, 6, 7, 8, 9, 10, 11, 12, 13, 14, 15, and 16 are drawings for explaining a semiconductor package manufacturing process according to some example embodiments. Specifically, FIG. 5, FIG. 7, FIG. 9, FIG. 11, FIG. 13, and FIG. 15 are cross-sectional views showing a semiconductor package fabricated in each of the processes of a semiconductor package manufacturing method according to some example embodiments, and FIG. 6, FIG. 8, FIG. 10, FIG. 12, FIG. 14, and FIG. 16 may be top plan views showing a semiconductor package fabricated in each of the processes of a semiconductor package manufacturing method according to some example embodiments. FIG. 5, FIG. 7, FIG. 9, FIG. 11, FIG. 13, and FIG. 15 may be drawings rotating the semiconductor package illustrated in FIG. 1, FIG. 2, and FIG. 4 180 degrees so that the upper surface faces downward and the lower surface faces upward. In FIG. 5, FIG. 7, FIG. 9, FIG. 11, FIG. 13, and FIG. 15, a surface facing the third direction D3 of each of the components (111, 113, 120, 130, 141, 143, 145, 151, 153, 161, 163, 211A, 211B, 213A, 213B) is referred to as an upper surface, and a surface facing the opposite direction of the third direction D3 is referred to as a lower surface.

Referring to FIG. 5 and FIG. 6, after peeling off a carrier substrate (not shown) positioned on the lower surfaces of the semiconductor chip 110 and the support member 120, a plurality of insulating layers 141, 143, 145, a first seed layer 151 and a metal pattern 153 may be formed on the lower surface of the semiconductor chip 110 and the support member 120. The process of forming the insulating layers 141, 143, 145 may be performed by lamination, coating, chemical vapor deposition (chemical vapor deposition, CVD), physical vapor deposition (physical vapor deposition, PVD), or a combination thereof.

First, a first insulating layer 141 may be formed on the lower surfaces of the semiconductor chip 110 and the support member 120. Then, by etching a portion of the first insulating layer 141 through a photolithography and etching process, a first opening OP1 exposing a portion of the lower surface of the connection pad 113 may be formed. Next, after forming a second insulating layer 143 on the lower surface of the first insulating layer 141, a second opening OP2 exposing a portion of the lower surface of the connection pad 113 may be formed by etching a portion of the second insulating layer 143 through a photolithography and etching process. Next, after forming conductive material on the lower surface of the second insulating layer 143, the first seed layer 151 and metal pattern 153 may be formed by patterning the conductive material through a photolithography and etching process. The process of forming the conductive material on the second insulating layer 143 may be performed by, for example, plating, chemical vapor deposition (CVD), physical vapor deposition (PVD), or any combination thereof.

Next, a third insulating layer 145 may be formed on the lower surfaces of the second insulating layer 143, the first seed layer 151, and the metal pattern 153. Subsequently, a third opening OP3 and a fourth opening OP4 may be formed by etching a portion of the third insulating layer 145 through photolithography and etching process. The third opening OP3 and the fourth opening OP4 may be formed by patterning a portion, which overlaps the metal pattern 153 in the third direction D3, of the third insulating layer 145. A portion of the lower surface of the metal pattern 153 may be exposed by the third opening OP3 and the fourth opening OP4. Referring to FIG. 6, the third opening OP3 may be a circular shape on a plane (e.g., a plane in the first and second directions D1 and D2). The fourth opening OP4 may be a ring shape on a plane (e.g., a plane in the first and second directions D1 and D2). On a plane (e.g., a plane in the first and second directions D1 and D2), the circular shape formed by the third opening OP3 may be positioned inside the ring shape formed by the fourth opening OP4. On a plane (e.g., a plane in the first and second directions D1 and D2), the inner diameter and outer diameter of the ring shape formed by the fourth opening OP4 may be larger than the diameter of the circular shape formed by the third opening OP3.

Next, as shown in FIG. 7 and FIG. 8, a second seed layer 161 may be formed on the lower surface 145L of the third insulating layer 145. At this time, the second seed layer 161 may fill the inside of the third opening OP3 and the fourth opening OP4. In some example embodiments, the process of forming the second seed layer 161 may be performed by plating, chemical vapor deposition (CVD), physical vapor deposition (PVD), or any combination thereof.

As shown in FIG. 9 and FIG. 10, after forming a conductive material on the lower surface 161L of the second seed layer 161, the UBM pad 163 may be formed by patterning the conductive material using a photolithography and etching process. The UBM pad 163 may be formed inside (e.g., at least partially inside, overlapping in the third direction D3, or any combination thereof) the third opening OP3, for example to at least partially fill the third opening OP3 (e.g., a portion of the third opening OP3 not filled with the second seed layer 161 material) with a first metal material which may be a material comprising the UBM pad 163 as described herein. The UBM pad 163 may cover the lower surface 161L of the second seed layer 161 formed along the side surface and the bottom surface of the third opening OP3. The UBM pad 163 may not be formed on (e.g., may not overlap in the third direction D3, may not cover, etc.) the lower surface 161L of the second seed layer 161 formed inside the fourth opening (OP4, see FIG. 5). The UBM pad 163 may have a circular shape on a plane (e.g., a plane in the first and second directions D1 and D2).

As shown in FIG. 11 and FIG. 12, a portion of the second seed layer 161 may be removed by a photolithography and etching process. For example, the remaining portions of the second seed layer 161, except for portions between the UBM pad 163 and the third insulating layer 145 and between the UBM pad 163 and the metal pattern 153, may be removed. At this time, the process of removing the second seed layer 161 may be controlled so that an undercut due to over etching the second seed layer 161 is not formed between the UBM pad 163 and the third insulating layer 145. As the second seed layer 161 filling the inside of the fourth opening OP4 is removed, a portion of the lower surface 153L of the metal pattern 153 may be exposed again.

Next, as shown in FIG. 13 and FIG. 14, a barrier pattern 210 may be formed covering a side surface 161S of the second seed layer 161 and the side surface 163S and a portion of the lower surface 163L of the UBM pad 163. Specifically, the barrier pattern 210 may be formed by depositing a metal or non-metal material covering the lower surface 145L of the third insulating layer 145, the side surface 161S of the second seed layer 161, and the side surface 163S and lower surface 163L of the UBM pad 163, and then patterning a portion of the metal or non-metal material using a photolithography and etching process. The forming the barrier pattern 210 may include filling at least the fourth opening OP4 with a second metal material that is different from the first metal material comprising the UBM pad 163 that at least partially fills the third opening OP3, where the second metal material may be a material comprising the barrier pattern 210 as described herein. For example, a thermal expansion coefficient of the second metal material comprising the barrier pattern 210 may have a value between a thermal expansion coefficient of an insulating material included in the third insulating layer 145 and a thermal expansion coefficient of the first metal material comprising the UBM pad 163. The barrier pattern 210 may cover a portion of the lower surface 145L of the third insulating layer 145, the side surface 163S and a portion of the lower surface 163L of the UBM pad 163, and the side surface 161S of the second seed layer 161. The barrier pattern 210 may have a ring shape on a plane (e.g., a plane in the first and second directions D1 and D2). An inner diameter of barrier pattern 210 may be smaller than the diameter of UBM pad 163. An outer diameter of barrier pattern 210 may be larger than the diameter of UBM pad 163.

As shown in FIG. 15 and FIG. 16, a connection bump 220 may be formed on the lower surface 163L of the UBM pad 163. As shown, the connection bump 220 may be formed on both at least a portion of the barrier pattern 210 (e.g., at least the lower surface 211BL of the second body portion 211B of the barrier pattern 210) and the a lower surface of the UBM pad 163 The connection bump 220 may be formed by applying ball attachment flux to the lower surface 163L of UBM pad 163, positioning the UBM pad 163 solder ball, and reflowing the ball attachment flux.

Although some example embodiments of the present inventive concepts have been described in detail above, the scope of the present inventive concepts is not limited thereto, and various modifications and improvements can be made by those skilled in the art using the basic concept of the present inventive concepts defined in the following claims, and they fall within the scope of the present inventive concepts. Additionally, what has been described for some example embodiments of the present inventive concepts may be equally applied to some other example embodiments even if they are not described for such other example embodiments.

What is claimed is:

1. A semiconductor package, comprising:
a redistribution structure;
a semiconductor chip on a surface of the redistribution structure;
a UBM pad on an opposite surface of the redistribution structure;
a barrier pattern surrounding a side surface of the UBM pad, the barrier pattern on at least a portion of a lower surface of the UBM pad; and
a connecting bump on the lower surface of the UBM pad.

2. The semiconductor package of claim 1, wherein:
the redistribution structure comprises insulating layers stacked in a vertical direction, and a metal pattern inside the insulating layers; and
the barrier pattern extends to be at least partially inside a portion of at least one of the insulating layers.

3. The semiconductor package of claim 2, wherein
a thermal expansion coefficient of the barrier pattern has a value between a value of a thermal expansion coefficient of at least one of the insulating layers and a value of a thermal expansion coefficient of the UBM pad.

4. The semiconductor package of claim 2, wherein
the barrier pattern comprises:
a first body portion extending to be at least partially inside the at least one of the insulating layers, the first body portion having a lower surface that contacts a lower surface of the metal pattern, the first body portion overlapping a first portion of the side surface of the UBM pad in a horizontal direction, the horizontal direction extending parallel to the surface of the redistribution structure;
a first protruding portion protruding outward from an outer side surface of the first body portion;
a second body portion on the lower surface of the first body portion and overlapping a remaining portion of the side surface of the UBM pad except the first portion of the side surface of the UBM pad in the horizontal direction; and
a second protruding portion protruding inwardly from an inner side surface of the second body portion.

5. The semiconductor package of claim 4, wherein:
the first protruding portion covers at least a portion of a lower surface of the insulating layers; and
the second protruding portion covers at least the portion of the lower surface of the UBM pad.

6. The semiconductor package of claim 5, wherein
the second protruding portion between the connecting bump and at least the portion of the lower surface of the UBM pad.

7. The semiconductor package of claim 1, wherein:
a shape of the UBM pad on a plane extending parallel to the surface of the redistribution structure is a circular shape; and
a shape of the barrier pattern on the plane is a ring shape surrounding the side surface of the UBM pad.

8. The semiconductor package of claim 7, wherein
an inner diameter of the barrier pattern is smaller than a diameter of the UBM pad, and
an outer diameter of the barrier pattern is larger than the diameter of the UBM pad.

9. The semiconductor package of claim 7, wherein
the redistribution structure comprises insulating layers stacked in a vertical direction, and a metal pattern inside the insulating layers,
the barrier pattern extends to be at least partially inside a portion of at least one of the insulating layers,
the semiconductor package further includes a seed layer between the UBM pad and the insulating layers,
wherein a shape of the seed layer on the plane is a circular shape.

10. The semiconductor package of claim 9, wherein
a side surface of the seed layer protrudes further outward in a horizontal direction from a center of the UBM pad, compared to the side surface of the UBM pad.

11. The semiconductor package of claim 9, wherein
the barrier pattern covers a side surface of the seed layer and at least a portion of a lower surface of the seed layer.

12. The semiconductor package of claim 9, wherein:
the side surface of the UBM pad protrudes further outward in a horizontal direction from a center of the UBM pad than a side surface of the seed layer; and
at least a portion of the barrier pattern is within an undercut region defined between an upper surface of the UBM pad and a lower surface of the insulating layers.

13. The semiconductor package of claim 1, wherein
the barrier pattern comprises at least one of aluminum, silver, or tin.

14. A semiconductor package manufacturing method, comprising:
forming a first insulating layer and a second insulating layer on a surface of a semiconductor chip;
forming a redistribution structure on the second insulating layer;
forming a third insulating layer on the redistribution structure;
exposing a portion of the redistribution structure based on etching a portion of the third insulating layer;
forming a UBM pad on the exposed portion of the redistribution structure;
forming a barrier pattern surrounding a side surface of the UBM pad, the barrier pattern on at least a portion of a lower surface of the UBM pad; and
forming a connection bump on both the barrier pattern and the lower surface of the UBM pad.

15. The semiconductor package manufacturing method of claim 14, wherein
the exposing the portion of the redistribution structure includes forming a first opening and a second opening based on patterning the third insulating layer;
the first opening has a circular shape on a plane extending parallel to an upper surface of the redistribution structure; and
the second opening has a ring shape surrounding the first opening on the plane.

16. The semiconductor package manufacturing method of claim 15, wherein:
the forming the UBM pad comprises filling the first opening with a first metal material; and
the forming the barrier pattern comprises filling the second opening with a second metal material, the second metal material different from the first metal material.

17. The semiconductor package manufacturing method of claim 16, wherein
a thermal expansion coefficient of the second metal material has a value between a value of a thermal expansion coefficient of an insulating material included in the third insulating layer and a value of a thermal expansion coefficient of the first metal material.

18. A semiconductor package, comprising:
a semiconductor chip including a connecting pad;
a molding member covering an upper surface and a side surface of the semiconductor chip;
a first insulating layer covering a lower surface of the semiconductor chip and at least a portion of the connection pad;
a second insulating layer on the first insulating layer;
a first seed layer on the second insulating layer and connected to the connection pad;
a metal pattern on the first seed layer;
a third insulating layer covering both the first seed layer and the metal pattern;
a UBM pad extending to be at least partially inside the third insulating layer and connected to the metal pattern;
a barrier pattern extending to be at least partially inside the third insulating layer to be connected to the metal pattern, the barrier pattern surrounding a side surface of the UBM pad, the barrier pattern on at least a portion of a lower surface of the UBM pad; and
a connecting bump on the lower surface of the UBM pad.

19. The semiconductor package of claim 18, wherein
the barrier pattern comprises:
a first body portion extending to be at least partially inside the third insulating layer, the first body portion having a lower surface that contacts a lower surface of the metal pattern, the first body portion overlapping a first portion of the side surface of the UBM pad in a horizontal direction, the horizontal direction extending parallel to a surface of the semiconductor chip;
a first protruding portion protruding outward from an outer side surface of the first body portion;
a second body portion on the lower surface of the first body portion and overlapping a remaining portion of the side surface of the UBM pad except the first portion of the side surface of the UBM pad in the horizontal direction; and
a second protruding portion protruding inwardly from an inner side surface of the second body portion.

20. The semiconductor package of claim 18, wherein
a thermal expansion coefficient of the barrier pattern has a value between a value of a thermal expansion coefficient of the second insulating layer and a value of a thermal expansion coefficient of the UBM pad.
